(19) United States
(12) Patent Application Publication
(10) Pub. No.: US 2024/0414847 A1
(43) Pub. Date: Dec. 12, 2024

(54) MOUNT BOARD AND METHOD OF MANUFACTURING THE SAME

(71) Applicant: DENSO CORPORATION, Kariya-city (JP)

(72) Inventor: Takeshi KAZAMA, Kariya-city (JP)

(21) Appl. No.: 18/734,526

(22) Filed: Jun. 5, 2024

(30) Foreign Application Priority Data
Jun. 7, 2023 (JP) 2023-094122

(51) Int. Cl. H05K 1/18; H05K 3/12; H05K 3/34

(52) U.S. Cl. CPC H05K 1/181; H05K 3/12; H05K 3/341

(57) ABSTRACT

A mount board to be attached to a housing as an attachment target includes a component and a mount portion on which the component is mounted while deviating from a designed mount location of the mount portion. The mount board includes at least one attachment member joined to the mount portion. The at least one attachment member is configured to be attached to the housing. The at least one attachment member includes a configuration defined to be in conformity with information about the deviation of the component from the designed mount location of the mount portion.

### CROSS-REFERENCE TO RELATED APPLICATION

This application is based on and claims the benefit of priority from Japanese Patent Application No. 2023-094122 filed on Jun. 7, 2023, the disclosure of which is incorporated in its entirety herein by reference.

### TECHNICAL FIELD

The present disclosure relates to mount boards and methods of manufacturing a mount board.

### BACKGROUND

Japanese Patent Application Publication No. 2003-304038 discloses a printed board that includes a product board on which components are mounted, a break-away board, and joints that join the product board and the break-away board to each other. The break-away board is used for fixture of the printed board when components are mounted on the product board. Cutting the joints of the printed board allows division of the printed board into the product board, on which components are implemented, and the break-away board. The product board on which the components are implemented is mounted to, for example, a housing as a mounting target of the product board.

### SUMMARY

At least one component, such as an image sensor, to be mounted on a mount board, such as a product board set forth above, require high mount-location accuracy with reference to a housing to which the mount board is mounted. For this reason, such a component is needed to be mounted on a predetermined corresponding designed location of the mount board with reference to the housing.

In particular, the mount location of at least one component with reference to the housing depends on the actual mount location of the mount board to the housing. For this reason, the mount board must also be mounted on a predetermined corresponding designed location of the housing.

At least one component may unfortunately be mounted on a location of the mount board; the location is deviated from a predetermined corresponding designed location of the mount board.

This may cause, even if the mount board is mounted to the predetermined corresponding designed location of the housing, the at least one component to be deviated from the predetermined corresponding designed location of the mount board with reference to the housing. This deviation of the at least one component from the corresponding designed location of the mount board with reference to the housing may result in a decrease in performance of the at least one component especially if the at least one component requires high mount-location accuracy with reference to the housing.

From this viewpoint, the present disclosure seeks to provide mount boards to be mounted to a housing, each of which enables at least one component mounted on a location thereof deviated from a corresponding designed location to have a higher mount-location accuracy with reference to the housing.

Additionally, the present disclosure seeks to provide methods of manufacturing a mount board to be mounted to a housing; the mount board enables at least one component mounted on a location thereof deviated from a corresponding designed location to have a higher mount-location accuracy with reference to the housing.

A first exemplary aspect of the present disclosure provides a mount board to be attached to a housing as an attachment target. The mount board includes a component and a mount portion on which the component is mounted while deviating from a designed mount location of the mount portion. The mount board includes at least one attachment member joined to the mount portion. The at least one attachment member is configured to be attached to the housing. The at least one attachment member has a configuration defined to be in conformity with information about the deviation of the component from the designed mount location of the mount portion.

A second exemplary aspect of the present disclosure provides an assembly board. The assembly board includes a plurality of mount boards, each of the mount boards is the mount board according to the first exemplary aspect, and a frame arranged to surround the mount boards and combine the mount boards with each other as an assembly. Each of the mount boards includes at least one joint joined to the mount portion. The at least one joint of each of the mount boards is configured to be cuttable for separation of the corresponding one of the mount boards from the assembly board. The at least one joint serves as the at least one attachment member.

The third exemplary aspect of the present disclosure provides a method of manufacturing a plurality of mount boards to be attached to a housing. The method includes
(I) Preparing an assembly board that includes the plurality of mount boards, each of which comprising a mount portion and at least one joint joined to the mount portion, and a frame arranged to surround the mount boards and combine the mount boards with each other as an assembly, the at least one joint of each mount board being configured to join the frame and the mount portion of the corresponding mount board
(II) Mounting a component on the mount portion of each of the mount boards in accordance with a designed mount location of the mount portion
(III) Detecting an actual mount location of the component on the mount portion of each of the mount boards
(IV) Determining whether the detected actual mount location of the component on the mount portion of each of the mount boards deviates from the designed mount location of the mount portion of the corresponding one of the mount boards
(V) Calculating, in response to determination that the detected actual mount location of the component on the mount portion of at least one mount board in the mount boards deviates from the designed mount location of the mount portion of the corresponding at least one mount board, information about the deviation of the component of the mount portion of the at least one mount board from the designed mount location of the mount portion thereof
(VI) Cutting the at least one joint of each of the mount boards to accordingly separate each of the mount boards from the assembly board.

The cutting step includes cutting, in response to determination that the detected actual mount location of the component on the mount portion of the at least one mount board deviates from the designed mount location of the mount portion of the corresponding at least one mount board, the at least one joint of the at least one mount board in accordance with the calculated information about the deviation of the component of the mount portion of the at least one mount board from the designed mount location of the mount portion thereof. The at least one joint of each of the mount boards after the cutting step serves as at least one attachment member to be attached to the housing. The at least one attachment member of the at least one mount board has a configuration defined to be in conformity with the calculated information about the deviation of the component from the designed mount location of the mount portion of the at least one mount board.

Each of the first to third exemplary aspects results in, even if the component is mounted on the mount portion of at least one mount board with its actual mount portion deviating from the designed mount location of the mount portion, the actual mount location of the component with reference to the housing approximating the designed mount location of the component with reference to the housing. This therefore improves the accuracy of the actual mount location of the component with reference to the housing.

### BRIEF DESCRIPTION OF THE DRAWINGS

Other aspects of the present disclosure will become apparent from the following description of embodiments with reference to the accompanying drawings in which:

FIG. 1 is a plan view schematically illustrating an assembly board including mount boards according to an example embodiment;

FIG. 2 is a plan view schematically illustrating a mount board cut away from the assembly board;

FIG. 3 is a plan view schematically illustrating the mount board according to the exemplary embodiment being attached to a housing;

FIG. 4 is a plan view schematically illustrating a comparative example where an actual mount location of a component is inclined with respect to a designed mount location on a mount portion of the mount board;

FIG. 5 is a plan view schematically illustrating the comparative example where the mount board with the component being inclined with respect to the designed mount location is attached to a housing;

FIG. 6 is a plan view schematically illustrating the exemplary embodiment where the actual mount location of the component is inclined with respect to the designed mount location on the mount portion of the mount board;

FIG. 7 is a plan view schematically illustrating the exemplary embodiment where the mount board with the component being inclined with respect to the designed mount location is attached to the housing;

FIG. 8 is a plan view schematically illustrating the assembly board before the mount boards according to the exemplary embodiment being mounted thereon;

FIG. 9 is a plan view schematically illustrating the assembly board after the mount boards according to the exemplary embodiment being mounted thereon;

FIG. 10 is a flowchart schematically illustrating a method of manufacturing the mount board according to the exemplary embodiment;

FIG. 11A is an enlarged plan view schematically illustrating how to cut the mount board with the component being inclined with respect to the designed mount location;

FIG. 11B is an enlarged plan view schematically illustrating how to cut the mount board with no inclination; and

FIG. 12 is an enlarged view schematically illustrating how to cut a mount board with the component being linearly deviated from the designed mount location.

### DETAILED DESCRIPTION OF EMBODIMENTS

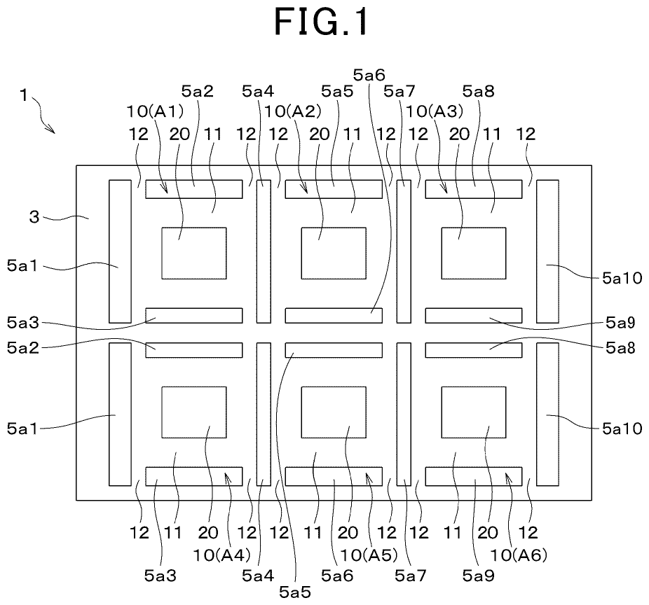

The following describes an exemplary embodiment of the present disclosure with reference to FIGS. 1 to 11B. In the embodiment and its modifications, descriptions of like parts between the exemplary embodiment and its modifications, to which like reference characters are assigned, are omitted or simplified to avoid redundant descriptions.

FIG. 1 illustrates an assembly board 1 including mount boards 10 according to the exemplary embodiment. The assembly board 1 is configured as a printed circuit board (PCB), which has, for example, a substantially rectangular plate-like shape. The assembly board 1 is comprised of an insulating substrate with opposing first and second major surfaces and one or more conductive wiring patterns printed on, for example, the first major surface of the insulating substrate. For example, the assembly board 1 includes six mount boards 10 according to the exemplary embodiment. The six mount boards 10 of the assembly board 1 can be configured to be individually cut away from the assembly board 1.

For example, the six mount boards 10 are arranged in two rows and three columns in the respective lateral and longitudinal directions of the assembly board 1.

For example, in FIG. 1, three mount boards 10 arranged in the upper row from left to right will also be referred to as an upper-left mount board 10A1, an upper-center mount board 10A2, and an upper-right mount board 10A3. Similarly, the remaining three mount boards 10 arranged in the lower row from left to right will also be referred to as a lower-left mount board 10A4, a lower-center mount board 10A5, and a lower-right mount board 10A6.

The assembly board 1 includes a frame 3 that surrounds the six mount boards 10 and combines the six mount boards 10 with each other as an assembly. The assembly board 1 also includes a plurality of cutouts 5 located between the assembly of the mount boards 10 and the frame 3.

Each of the cutouts 5 has a rectangular shape when viewed in the direction perpendicular to the first and second major surfaces of the assembly board 1.

The cutouts 5 include a first group of cutouts 5 provided for the upper-row mount boards 10A1 to 10A3 and a second group of cutouts 5 provided for the lower-row mount boards 10A4 to 10A6.

The cutouts 5 in the first group include a left-side cutout 5a1, a top cutout 5a2, a bottom cutout 5a3, a common side cutout 5a4 for the upper-left mount board 10A1. The cutouts 5 in the first group include the common side cutout 5a4, a top cutout 5a5, a bottom cutout 5a6, and a common side cutout 5a7 for the upper-center mount board 10A2. The cutouts 5 in the first group include the common side cutout 5a7, a top cutout 5a8, a bottom cutout 5a9, and a right-side cutout 5a10 for the upper-right mount board 10A3.

The left-side cutout 5a1, top cutout 5a2, bottom cutout 5a3, and common side cutout 5a4 are arranged to have a substantially rectangular shape to surround the upper-left mount board 10A1. This enables the upper-left mount board 10A1 to be more easily cut away from the assembly board 1. Similarly, the common side cutout 5a4, top cutout 5a5, bottom cutout 5a6, and common side cutout 5a7 are arranged to have a substantially rectangular or square shape to surround the upper-center mount board 10A2. This enables the upper-center mount board 10A2 to be more easily cut away from the assembly board 1. Additionally, the common side cutout 5a7, top cutout 5a8, bottom cutout 5a9, and right-side cutout 5a10 are arranged to have a substantially rectangular or square shape to surround the upper-right mount board 10A3. This enables the upper-right mount board 10A3 to be more easily cut away from the assembly board 1.

The cutouts 5 in the second group similarly include a left-side cutout 5a1, a top cutout 5a2, a bottom cutout 5a3, a common side cutout 5a4 for the lower-left mount board 10A4, the common side cutout 5a4, a top cutout 5a5, a bottom cutout 5a6, and a common side cutout 5a7 for the lower-center mount board 10A5, the common side cutout 5a7, a top cutout 5a8, a bottom cutout 5a9, and a right-side cutout 5a10 for the lower-right mount board 10A6. The arrangement of the cutouts 5a1 to 5a10 in the second group around the lower-row mount boards 10A4 to 10A6 is identical to the arrangement of the cutouts 5a1 to 5a10 in the first group around the upper-row mount boards 10A1 to 10A3.

Each mount board 10 serves as a PCB on which various types of components are mounted.

Each mount board 10 includes a mount portion 11 and joints 12 joined to the mount portion 11. The mount portion 11 has a thin rectangular plate-like shape, and has opposing first and second major surfaces, and the first major surface of the mount portion 11 of each mount board 10 serves as a mount surface. The mount surface of the mount portion 11 has a center point O serving as a reference point O.

The following describes the relationships between the cutouts 5a1 to 5a10 in the first group around the upper-row mount boards 10A1 to 10A3 and the corresponding joints 12.

Each of the left-side cutout 5a1, the common side cutout 5a4, the common side cutout 5a7, and the right-side cutout 5a10 has opposing first and second ends in its longitudinal direction that corresponds to the lateral direction of the assembly board 1.

The first end of the left-side cutout 5a1 is arranged to face a first end of the top cutout 5a2, which is closer to the left-side cutout 5a1 than a second end of the top cutout 5a2 is, with a part of the frame 3 therebetween. The part of the frame 3 between the first end of the left-side cutout 5a1 and the first end of the top cutout 5a2 serves as a corresponding one of the joints 12. The second end of the top cutout 5a2, which is closer to the first end of the common side cutout 5a4 is, is arranged to face the first end of the common side cutout 5a4 with a part of the frame 3 therebetween. The part of the frame 3 between the second end of the top cutout 5a4 and the first end of the common side cutout 5a4 serves as a corresponding one of the joints 12.

The first end of the common side cutout 5a4 is arranged to face a first end of the top cutout 5a5, which is closer to the common side cutout 5a4 than a second end of the top cutout 5a5 is, with a part of the frame 3 therebetween. The part of the frame 3 between the first end of the common side cutout 5a4 and the first end of the top cutout 5a5 serves as a corresponding one of the joints 12. The second end of the top cutout 5a5, which is closer to the first end of the common side cutout 5a7, is arranged to face the first end of the common side cutout 5a7 with a part of the frame 3 therebetween. The part of the frame 3 between the second end of the top cutout 5a5 and the first end of the common side cutout 5a7 serves as a corresponding one of the joints 12.

The first end of the common side cutout 5a7 is arranged to face a first end of the top cutout 5a8, which is closer to the common side cutout 5a7 than a second end of the top cutout 5a8 is, with a part of the frame 3 therebetween. The part of the frame 3 between the first end of the common side cutout 5a7 and the first end of the top cutout 5a8 serves as a corresponding one of the joints 12. The second end of the top cutout 5a8, which is closer to the first end of the right-side cutout 5a10, is arranged to face the first end of the right-side cutout 5a10 with a part of the frame 3 therebetween. The part of the frame 3 between the second end of the top cutout 5a8 and the first end of the right-side cutout 5a10 serves as a corresponding one of the joints 12.

The second end of the left-side cutout 5a1 is arranged to face a first end of the bottom cutout 5a3, which is closer to the left-side cutout 5a1 than a second end of the bottom cutout 5a3 is, with a part of the frame 3 therebetween. The part of the frame 3 between the second end of the left-side cutout 5a1 and the first end of the bottom cutout 5a3 serves as a corresponding one of the joints 12. The second end of the bottom cutout 5a3, which is closer to the second end of the common side cutout 5a4 is, is arranged to face the second end of the common side cutout 5a4 with a part of the frame 3 therebetween. The part of the frame 3 between the second end of the bottom cutout 5a4 and the second end of the common side cutout 5a4 serves as a corresponding one of the joints 12.

The second end of the common side cutout 5a4 is arranged to face a first end of the bottom cutout 5a6, which is closer to the common side cutout 5a4 than a second end of the bottom cutout 5a6 is, with a part of the frame 3 therebetween. The part of the frame 3 between the second end of the common side cutout 5a4 and the first end of the bottom cutout 5a6 serves as a corresponding one of the joints 12. The second end of the bottom cutout 5a6, which is closer to the second end of the common side cutout 5a7, is arranged to face the second end of the common side cutout 5a7 with a part of the frame 3 therebetween. The part of the frame 3 between the second end of the bottom cutout 5a6 and the second end of the common side cutout 5a7 serves as a corresponding one of the joints 12.

The second end of the common side cutout 5a7 is arranged to face a first end of the bottom cutout 5a9, which is closer to the common side cutout 5a7 than a second end of the bottom cutout 5a9 is, with a part of the frame 3 therebetween. The part of the frame 3 between the second end of the common side cutout 5a7 and the first end of the bottom cutout 5a9 serves as a corresponding one of the joints 12. The second end of the bottom cutout 5a9, which is closer to the second end of the right-side cutout 5a10, is arranged to face the second end of the right-side cutout 5a10 with a part of the frame 3 therebetween. The part of the frame 3 between the second end of the bottom cutout 5a9 and the second end of the right-side cutout 5a10 serves as a corresponding one of the joints 12.

The relationships between the cutouts 5a1 to 5a10 in the second group around the lower-row mount boards 10A4 to 10A6 and the corresponding joints 12 are identical to the relationships between the cutouts 5a1 to 5a10 in the first group around the upper-row mount boards 10A1 to 10A3 and the corresponding joints 12.

The joint 12 of each mount board 10 is joined to the frame 3 of the assembly board 1. One or more components 20 can be, as illustrated in FIG. 1, mounted on the mount surfaces of the mount portions 11 of the respective mount boards 10.

For example, a component 20 is mounted on the mount surface of the mount portion 11 of each mount board 10 with reflow soldering, thus being implemented on the mount portion 11. After the reflow soldering process, the boundary between the frame 3 and the joints 12 are cut, so that the six mount boards 10 are separated away from the assembly board 1.

The mount portion 11 of each mount board 10 has a substantially rectangular shape when viewed in the direction perpendicular to the first and second major surfaces. The mount portion 11 of each mount board 10 has a pair of long sides 111 and 112 and a pair of short sides 113 and 114; these long and short sides 111 to 114 constitute the substantially rectangular shape of the mount portion 11. The long sides 111 and 112 are arranged to extend linearly to be parallel to one another, and the short sides 113 and 114, which is shorter in length than the long sides 111 and 112, are also arranged to extend linearly to be parallel to one another.

The long side 111 has both first and second end portions respectively joined to first ends of the short sides 113 and 114. Similarly, the long side 112 has both first and second end portions respectively joined to second ends of the short sides 113 and 114; the second ends of the short sides 113 and 114 are opposite to the first ends thereof.

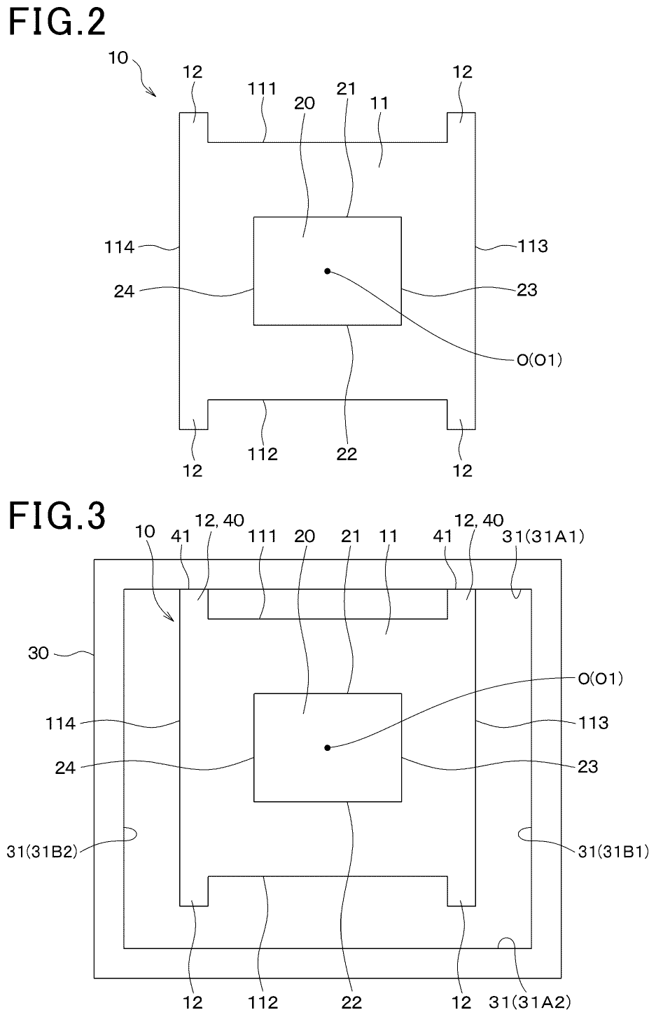

Each of the joints 12 is, as illustrated in FIG. 2, arranged to extend outwardly from the corresponding one of (i) the first end of the long side 111, (ii) the second end of the long side 111, (iii) the first end of the long side 112, and (iv) the second end of the long side 112 in a direction parallel to the short sides 113 and 114. Each of the joints 12 has a predetermined length in a direction parallel to the short sides 113 and 114 and a predetermined width in a direction parallel to the long sides 111 and 112.

That is, each mount board 10 is cut away from the assembly board 1 with each of the joints 12 being jointed to the corresponding one of (i) the first end of the long side 111, (ii) the second end of the long side 111, (iii) the first end of the long side 112, and (iv) the second end of the long side 112.

As the component 20 mounted on the mount portion 11 of each mount board 10, an image sensor, such as a charge coupled device (CCD) image sensor or a complementary metal oxide semiconductor (CMOS) image sensor, can be used; the image sensor 20 can be applied to unillustrated image capturing apparatuses.

The following describes an example where the component 20 of each mount board 10 is an image sensor applied to an image capturing apparatus installed in a vehicle.

The following describes one mount board 10 on which the component 20, that is an image sensor, is implemented.

The component 20, which is an image sensor, requires accurate alignment with respect to the image capturing apparatus.

The component, that is an image sensor, 20 of the mount board 10 has a substantially rectangular shape when viewed in the direction perpendicular to the first and second major surfaces of the mount portion 11. Specifically, the component 20 has, as illustrated in FIG. 2, a center point O1 serving as a reference point O1, and a pair of first side faces 21 and 22 respectively corresponding to the long sides 111 and 112 of the mount portion 11, and a pair of second side faces 23 and 24 respectively corresponding to the short sides 113 and 114 of the mount portion 11.

A designed mount location, i.e., a designed mount region, of the component 20 on the mount surface of the mount portion 11 is determined such that
(I) The center point O1 of the component 20 is aligned with the center point O of the mount surface of the mount portion 11
(II) The first side faces 21 and 22 are parallel to the respective long sides 111 and 112 of the mount portion 11
(III) The second side faces 23 and 24 are parallel to the respective short sides 113 and 114 of the mount portion 11

Note that another component or one or more other components can be mounted on the mount portion 11 of each mount board 10.

The mount board 10, which has been cut away from the assembly board 1, is, as illustrated in FIG. 3, mounted to a housing 30 of an unillustrated image capturing apparatus. The housing 30 constitutes a casing of the image capturing apparatus, and is directly attached to a vehicle. The housing 30 has, for example, a bottomed rectangular-tubular shape with an inner hollow space, and is configured to enable the mount board 10 to be installed in the inner hollow space of the housing 30.

The housing 30 has four inner peripheral faces 31, i.e., a pair of first inner peripheral faces 31A1 and 31A2 and a pair of second inner peripheral faces 31B1 and 31B2. The housing 30 has a predetermined center axis defined by the four inner peripheral faces 31.

That is, when the mount board 10 is installed in the inner hollow space of the housing 30 with the center point O being on the center axis of the housing 30, the long sides 111 and 112 of the mount portion 11 are arranged to face the respective first inner peripheral faces 31A1 and 31A2 of the housing 30, and the short sides 113 and 114 of the mount portion 11 are arranged to face the respective second inner peripheral faces 31B1 and 31B2 of the housing 30.

Specifically, the mount board 10 is installed in the inner hollow space of the housing 30 while selected two of the joints 12 are attached to a corresponding one of the inner peripheral faces of the housing 30. The selected two of the joints 12 will be referred to as attachment members 40. The exemplary embodiment uses the joints 12 extending linearly from the long side 111 of the mount portion 11 as the attachment members 40. That is, the attachment members 40 of the mount portion 11 of the mount board 10 are attached to the first inner peripheral face 31A1 of the housing 30.

Each of the joints 12 has a face at an extending end thereof; the end face of each of the attachment members 40 will be referred to as an attachment face 41. While the mount portion 10 is installed in the inner hollow space of the housing 30, the attachment faces 41 of the attachment members 40 are attached to the first inner peripheral face 31A1 of the housing 30. More specifically, the attachment faces 41 of the attachment members 40 are pressed to abut onto the first inner peripheral face 31A1 of the housing 30, resulting in the mount board 10 being fixedly attached to the housing 30. This fixed attachment of the mount board 10 to the housing 30 determines a mount location of the mount board 10 with reference to the housing 30, resulting in a mount location of the component 20 mounted on the mount board 10 with reference to the housing 30 being determined. That is, the designed mount location of the component 20 with reference to the housing 30 is based on the designed mount location of the mount board 10 with reference to the housing 30.

The designed mount location of the component 20 with reference to the mount board 10 according to the exemplary embodiment is, as illustrated in FIG. 3, determined such that
(I) The center point O1 of the component 20 is aligned with the center point O of the mount surface of the mount portion 11
(II) The first side faces 21 and 22 are parallel to the respective long sides 111 and 112 of the mount portion 11
(III) The second side faces 23 and 24 are parallel to the respective short sides 113 and 114 of the mount portion 11

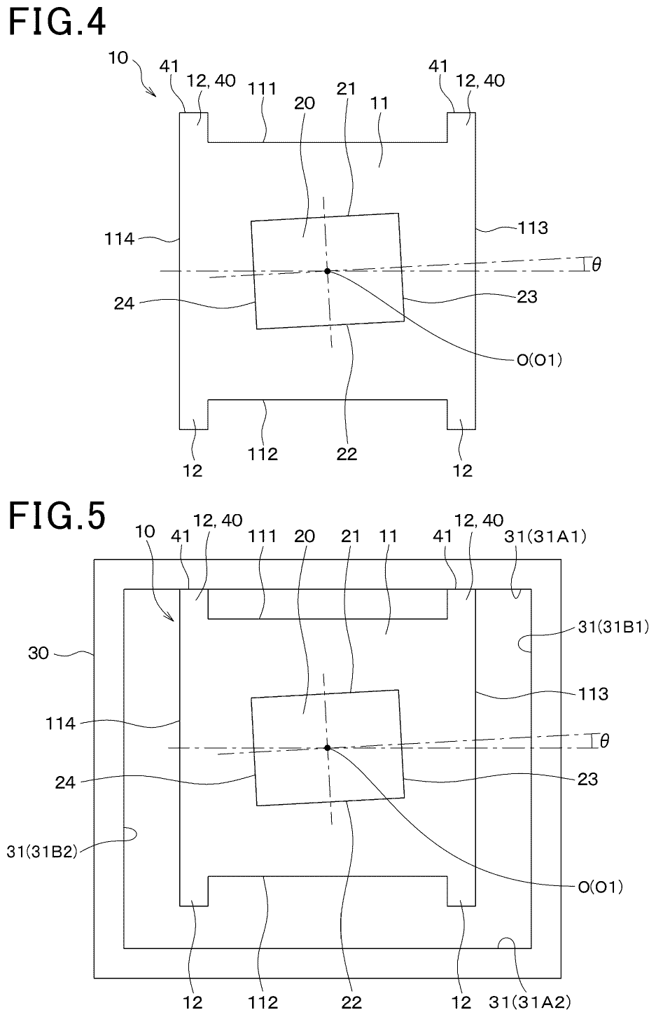

The component 20 may be mounted on the mount surface of the mount portion 11 of the mount board 10 while being misaligned with respect to the predetermined mount location thereon with reference to the mount board 10. For example, FIG. 4 illustrates a comparative example where an actual mount location of the component 20 is inclined with respect to the designed mount location on the mount surface of the mount portion 11 by an angle θ with the center point O1 of the component 20 being aligned with the center point O of the mount surface of the mount portion 11. That is, the comparative example shows that the component 20 is mounted on the mount portion 11 while each of the first side faces 21 and 22 is inclined with respect to the corresponding one of the long sides 111 and 112 of the mount portion 11 by the angle θ and each of the second side faces 23 and 24 is inclined with respect to the corresponding one of the short sides 113 and 114 of the mount portion 11 by the angle θ.

Let us assume that, as illustrated in FIG. 4, the attachment face 41 of each of the two attachment members 40, which has been cut away from the assembly board 1, is parallel to the long sides 111 and 112 of the mount board 10.

In this assumption, additionally let us assume that the attachment faces 41 of the attachment members 40 of the mount board 10 are pressed to be joined to the first inner peripheral face 31A1 of the housing 30 with the center point O of the mount board 10 matching the predetermined center axis of the housing 30, resulting in the mount board 10 being fixedly mounted to the housing 30.

This results in, as illustrated in FIG. 5, the component 20 being mounted to the housing 30 while the component 20 is inclined with reference to the designed mount location with reference to the housing 30 by the angle θ. This is because the mount location of the component 20 is based on the mount location of the mount board 10 with reference to the housing 30. That is, mounting the mount board 10 to the housing 30 while the component 20 is mounted on the mount portion 11 to be misaligned with the designed mount location with reference to the housing 30 would result in the component 20 mounted to the housing 30 having misalignment with the designed mount location with reference to the housing 30.

Misalignment of the component 20, which is an image sensor, with the designed mount location with reference to the housing 30 while the component 20 is inclined by the angle θ with respect to the designed mount location of the mount portion 11 would cause the component (image sensor) 20 of the image capturing apparatus to capture images being inclined. This would result in the image capturing apparatus performing one or more originally unnecessary software tasks of correcting the inclination of the captured images.

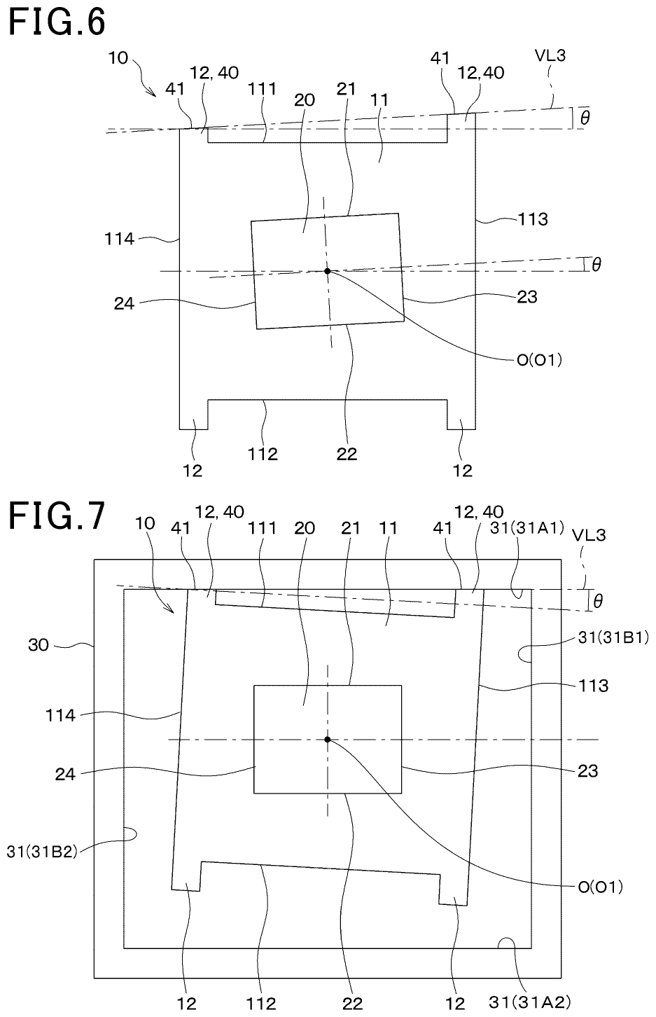

From this viewpoint, the mount board 10 according to the exemplary embodiment is configured such that, as illustrated in FIG. 6, each of the attachment members 40 has a configuration defined to be in conformity with deviation information about the component 20 from the designed mount location of the mount portion 11. The deviation information about the component 20 represents a directional deviation of the actual mount location of the component 20 of the at least one mount board 10 from the designed mount location of the component 20.

Specifically, the mount board 10 according to the exemplary embodiment is configured such that, as illustrated in FIG. 6, the attachment face 41 of each of the attachment members 40 is formed to have an inclination that is in conformity with the inclination of the component 20 with respect to the designed mount location of the mount portion 11.

More specifically, the mount board 10 is cut away from the assembly board 1 such that each attachment member 40 (12) has the attachment face 41 formed on the extending end thereof; the attachment face 41 is inclined by a predetermined angle with respect to a direction parallel to the long side 111; the predetermined angle matches the inclination angle θ of the component 20 with respect to the designed mount location of the mount portion 11. The predetermined angle made by a direction extending along the attachment face 41 and the direction parallel to the long side 111 matches the inclination angle θ of the component 20.

The mount board 10 is cut away from the assembly board 1 while the extending end of each attachment member 40 (12) is cut along a virtual plane VL3 extending by the angle θ with respect to the direction parallel to the long side 111. In other words, the extending end of each attachment member 40 is cut along the virtual cutting plane VL3 extending parallel to the first side faces 21 and 22 of the component 20, so that the attachment face 41 of the extending end of each attachment member 40 (12) formed by the cutting is parallel to the first side faces 21 and 22 of the component 20.

The following describes an actual mount location of the component 20 to the mount board 10, which has the attachment faces 41 set forth above, with the mount board 10 being attached to the housing 30 with reference to FIG. 7.

The attachment face 41 of each attachment member 40 (12), which is formed to be inclined in conformity with the inclination of the component 20 with respect to the designed mount location of the mount portion 11, is pressed to be fixed to the first inner face 31A1 of the housing 30. This results in, as illustrated in FIG. 7, the mount board 10 being mounted to the housing 30 with the long side 111 of the mount board 10 being inclined by the angle θ with respect to the first inner peripheral face 31A1 of the housing 30. This therefore enables, even if the component 20 is mounted on the mount portion 11 and inclined by the angle θ with respect to the designed mount location of the mount portion 11, the actual mount location of the component 20 with reference to the housing 30 to approximate the designed mount location of the component 20 with reference to the housing 30. Specifically, the component 20 is mounted to the housing 30 such that the first side faces 21 and 22 are parallel to the first inner peripheral face 31A1 of the housing 30.

This therefore eliminates, even if the component, i.e., an image sensor, 20 is mounted on the mount portion 11 and inclined by the angle θ with respect to the designed mount location of the mount portion 11, one or more originally unnecessary software tasks, such as captured-image correction tasks.

The configuration of the mount board 10 according to the exemplary embodiment has been described set forth above.

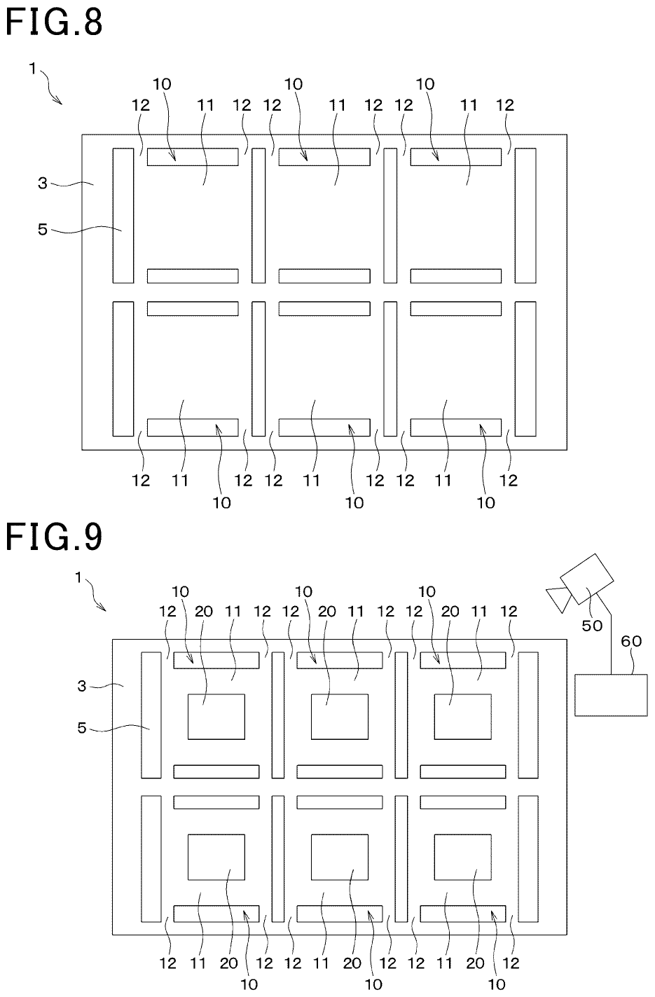

Next, the following describes a method of manufacturing the mount board 10 according to the exemplary embodiment with reference to FIGS. 8 to 10.

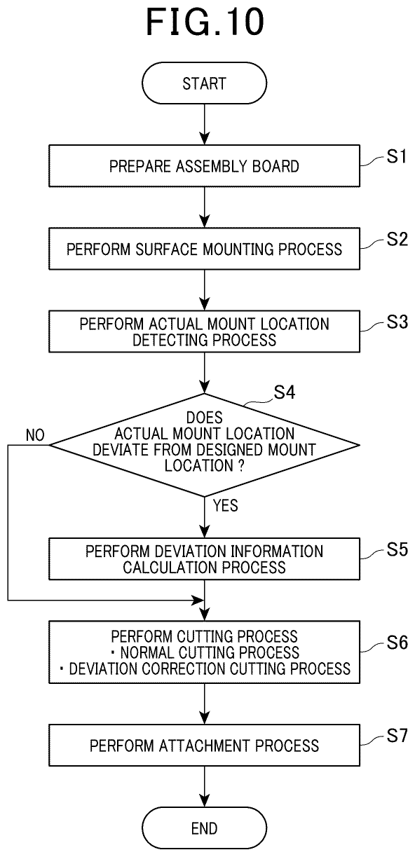

First, as illustrated in FIG. 8, the method performs a board preparing step of preparing the assembly board 1 on which the six mount boards 10 (10A1 to 10A6) are mounted as illustrated in FIG. 1 set forth above in step S1 of FIG. 10. Specifically, the assembly board 1 includes the frame 3, the cutouts 5 (5a1 to 5a10) of the first group for the upper-row mount boards 10A1 to 10A3, and the cutouts 5 (5a1 to 5a10) of the second group for the lower-row mount boards 10A4 to 10A6.

Next, the method performs a surface mounting process in step S2 of FIG. 10.

As a first example, the assembly board 1 has a center point, i.e., a reference point, and also has a first two-dimensional coordinate system defined around the center point. In the first two-dimensional coordinate system, a predetermined designed mount location, i.e., a predetermined designed rectangular mount region, for the component 20 is previously determined for each of the mount boards 10 (10A1 to 10A6).

As a second example, the mount surface of the mount portion of each of the mount boards 10 (10A1 to 10A6) has a second two-dimensional coordinate system defined around the center point O thereof. In the second two-dimensional coordinate system of each of the mount boards 10 (10A1 to 10A6), a predetermined designed mount location, i.e., a predetermined designed rectangular mount region, for the component 20 is previously determined for the corresponding one of the mount boards 10 (10A1 to 10A6).

The surface mounting process successively holds the components 20, and successively mounts the components 20 on the designed mount locations of the respective mount boards 10 (10A1 to 10A6).

Then, the surface mounting process solders the component 20 to the mount surface of the mount portion 11 of each of the mount boards 10 (10A1 to 10A6) with reflow soldering.

After the surface mounting process, the method performs an actual mount-location detecting process in step S3 of FIG. 10. Specifically, the actual mount-location detecting process prepares, in step S3 of FIG. 10, a camera 50 for capturing images of at least the first two-dimensional coordinate system of the assembly board 1, and an image processing apparatus 60 connected to the camera 50 for performing image processing of the captured images (see FIG. 9).

Specifically, the actual mount-location detecting process controls the camera 50 to capture one or more images of the first two-dimensional coordinate system of the assembly board 1 or the second two-dimensional coordinate system of each mount board 10. Then, the actual mount-location detecting process instructs the image processing apparatus 60 to perform image processing of the one or more captured images to accordingly detect an actual mount location of each component 20 in the first two-dimensional coordinate system of the assembly board 1 or an actual mount location of each component 20 in the second two-dimensional coordinate system of the corresponding mount board 10.

The actual mount-location detecting process in step S3 of the method can detect, using another measurement device, the actual mount location of each component 20 in the first two-dimensional coordinate system of the assembly board 1 or the actual mount location of each component 20 in the second two-dimensional coordinate system of the corresponding mount board 10.

Next, the method performs a deviation determination process in step S4 of FIG. 10. Specifically, the method compares the detected actual mount location of the component 20 of each mount board 10 with the designed mount location of the component 20 of the corresponding mount board 10 to accordingly determine whether the detected actual mount location of the component 20 of each mount board 10 deviates from the designed mount location of the component 20 of the corresponding mount board 1 in the deviation determination process in step S4.

In response to determination that the detected actual mount location of the component 20 of each mount board 10 does not deviate from the designed mount location of the component 20 of the corresponding mount board 1 (NO in step S4), the method proceeds to step S6 while skipping the operation in step S5.

Otherwise, in response to determination that the detected actual mount location of the component 20 of at least one mount board 10 deviates from the designed mount location of the component 20 of the corresponding mount board 1 (YES in step S4), the method performs a deviation information calculation process for the at least one mount board 10 in step S5 of FIG. 10.

Specifically, the deviation information calculation process uses the image processing apparatus 60 to calculate, for the at least one mount board 10, deviation information representing, for example, a directional deviation of the actual mount location of the component 20 of the at least one mount board 10 from the designed mount location of the component 20 of the at least one mount board 10.

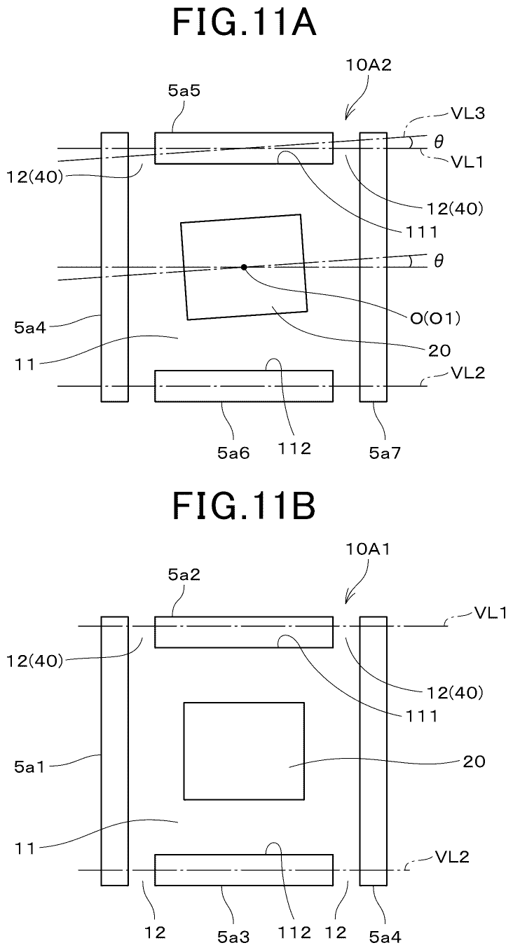

FIG. 11A shows an example where the actual mount location of the component 20 of the upper-center mount board 10A2 is misaligned with the designed mount location of the component 20 of the upper-center mount board 10A2, so that the designed mount location is inclined with respect to the designed mount location of the component 20 of the upper-center mount board 10A2 by an angle θ with the center point O1 of the component 20 being aligned with the center point O of the mount surface of the mount portion 11 of the upper-center mount board 10A2. More specifically, the first side face 21 of the component 20 mounted on the mount portion 11 of the upper-center mount board 10A2 is inclined with respect to the long side 111 of the mount board 10A2 by the angle θ.

In this example, the deviation information calculation process uses the image processing apparatus 60 to calculate, for the upper-center mount board 10A2, the deviation information representing, for example, a counterclockwise rotational deviation from the designed mount location of the component 20 by the angle θ.

Following the negative determination in step S4 of FIG. 10 or the deviation information calculation process in step S5 of FIG. 10, the method performs a cutting process in step S6 of FIG. 10.

Following the negative determination in step S4 of FIG. 10, the cutting process of the method performs a normal cutting process for all the mount boards 10.

Specifically, the normal cutting process uses, for example, an unillustrated cutting machine to cut the joints 12 of each mount board 10 in a direction parallel to the long side 111 of the corresponding mount board 10 to accordingly separate the corresponding mount board 10 from the frame 3 of the assembly board 1 in step S6.

For example, FIG. 11B schematically illustrates an example of the cutting process for the upper-left mount board 10A1 with no deviation.

Specifically, as illustrated in FIG. 11A, (i) cutting each joint 12, i.e., each attachment member 40, extending outwardly from the long side 111 of the mount portion 11 of the upper-left mount board 10A1 along a virtual cutting plane VL1 that passes a predetermined cutting point of the corresponding joint 12 in its length direction and is parallel to the long side 111 of the corresponding mount board 10 and (ii) cutting each joint 12 extending outwardly from the long side 112 of the mount portion 11 of the upper-left mount board 10A1 along a virtual cutting plane VL2 that passes a predetermined normal cutting point of the corresponding joint 12 in its length direction and is parallel to the long side 112 of the corresponding mount board 10 result in the upper-left mount board 10A1 being cut away from the assembly board 1.

In contrast, following the deviation information calculation process in step S5 of FIG. 10, the cutting process of the method performs a deviation correction cutting process for the at least one mount board 10, and performs the normal cutting process for the remaining one or more mount boards 10 with alignment.

Specifically, the deviation correction cutting process uses, for example, the unillustrated cutting machine to cut the attachment members 12 (40) of the at least one mount board 10 in accordance with the deviation information, i.e., the directional deviation of the actual mount location of the component 20 of the at least one mount board 10 from the designed mount location of the component 20. Additionally, the deviation correction cutting process uses, for example, the unillustrated cutting machine to cut each of the remaining joints 12 of the at least one mount board 10 in a direction parallel to the long side 112 of the corresponding one of the remaining mount boards 10.

For example, FIG. 11A schematically illustrates an example of the cutting process for the upper-center mount board 10A2 with the inclination by the angle θ set forth above.

Specifically, as illustrated in FIG. 11A, the deviation correction cutting process cuts each attachment member 12 (40) extending outwardly from the long side 111 of the mount portion 11 of the upper-center mount board 10A2 along the virtual cutting plane VL3 that has been rotated counterclockwise from the normal virtual cutting line VL1 by the angle θ; the virtual cutting line VL1 is parallel to the long side 111. Additionally, the deviation correction cutting process cuts each remaining joint 12 extending outwardly from the long side 112 of the mount portion 11 of the upper-center mount board 10A2 along the virtual cutting plane VL2 that passes through a predetermined normal cutting point of the corresponding joint 12 in its length direction and is parallel to the long side 112 of the corresponding mount board 10.

This results in all the six mount boards 10 being separated from the frame 3 of the assembly board 1.

Next, the method performs an attachment process of attaching each of the six mount boards 10 cut away from the assembly board 1 in step S7 of FIG. 10.

Specifically, the attachment process prepares six housings 30 of the image capturing apparatuses, and two-dimensionally arranges the six housings 30. Then, the attachment process installs the respective six mount boards 10 into the hollow spaces of the respective six housings 30. Then, the attachment process presses the attachment faces 41 of the attachment members 40 of each mount board 10 onto the first inner peripheral face 31A1 of the corresponding housing 30 to fixedly attach each mount board 10 to the corresponding housing 30.

In particular, as illustrated in FIGS. 6 and 7, the attachment face 41 of the extending end of each attachment member 40 of the at least one mount board 10 is parallel to the first side faces 21 and 22 of the component 20 whose actual mount location is inclined with respect to the designed mount location by the angle θ.

This results in, as illustrated in FIG. 7, the at least one mount board 10 being mounted to the housing 30 with the long side 111 of the at least one mount board 10 being inclined by the angle θ with respect to the first inner peripheral face 31A1 of the housing 30. This therefore enables, even if the component 20 is mounted on the mount portion 11 and inclined by the angle θ with respect to the designed mount location of the mount portion 11, the actual mount location of the component 20 with reference to the housing 30 to approximate the designed mount location of the component 20 with reference to the housing 30. Specifically, the component 20 of the at least one mount board 10 is mounted to the housing 30 such that the first side faces 21 and 22 are parallel to the first inner peripheral face 31A1 of the housing 30.

As described above, the mount board 10 according to the exemplary embodiment is comprised of the mount portion 11 on which the component 20 is mounted. The mount board 10 according to the exemplary embodiment is comprised of the attachment members 40 joined to the mount portion 11. Each of the attachment members 40 to be attached to the housing 30 has a configuration defined to be in conformity with the deviation information about the component 20 from the designed mount location of the mount portion 11. The deviation information about the component 20 represents a directional deviation of the actual mount location of the component 20 of the mount board 10 from the designed mount location of the component 20.

This therefore results in, even if the component 20 is mounted on the mount portion 11 of the mount board 10 with its actual mount portion deviating from the designed mount location of the mount portion 11, the actual mount location of the component 20 with reference to the housing 30 approximating the designed mount location of the component 20 with reference to the housing 30. This therefore improves the accuracy of the actual mount location of the component 20 with reference to the housing 30.

Additionally, the exemplary embodiment offers the following advantageous benefits.

The housing 30 has at least an inner peripheral face 31A1 to which the mount board 10 is attached, and each of the attachment members 40 of the mount board 10 has the attachment face 41 to be attached to the inner peripheral face 31A1 of the housing 31. The attachment face 41 of each of the attachment members 40 is formed to have an inclination that is in conformity with an inclination of the component 20 with respect to the designed mount location of the mount portion 11.

The inclination of the attachment face 41 of each of the attachment members 40, which is in conformity with an inclination of the component 20 with respect to the designed mount location of the mount portion 11, results in the actual mount location of the component 20 with reference to the housing 30 approximating the designed mount location of the component 20 with reference to the housing 30. This therefore improves the accuracy of the actual mount location of the component 20 with reference to the housing 30.

The assembly board 1 according to the exemplary embodiment includes the mount boards 10, and the frame 3 that surrounds the mount boards 10 and combines the mount boards 10 with each other as an assembly. Each mount board 10 includes the joints 12 joined to the frame 3. The joints 12 of each mount board 10 are configured to be cuttable for separation of the corresponding mount board from the assembly board 1. At least two of the joints 12 serve as the attachment members 40.

Each mount board 10 therefore has a simpler configuration as compared with a configuration that includes attachment members in addition to the joints 12.

The component 20 to be mounted on the mount portion 11 of each mount board 10 is an image sensor.

If the component 20, which is an image sensor, is mounted and inclined with respect to the designed mount location of the mount portion 11, this inclination of the component 20 would cause the component (image sensor) 20 of the image capturing apparatus to capture images being inclined. This would result in the image capturing apparatus performing one or more originally unnecessary software tasks of correcting the inclination of the captured images.

In contrast, the above configuration of the mount board 10 eliminates, even if the component 20, which is an image sensor, is mounted to be inclined with respect to the designed mount location of the mount portion 11, the need of performing one or more originally unnecessary software tasks of correcting the inclination of the captured images.

The exemplary embodiment of the present disclosure has been described set forth above. The present disclosure is not limited to the above exemplary embodiment, and can be variously modified for example as follows.

The mount board 10 according to the exemplary embodiment is attached to the housing 30 of the image capturing apparatus, but the mount board 10 can be attached to the housing of another apparatus.

The component 20 according to the exemplary embodiment is an image sensor, but another component, such as a receptacle connector or an insertable connector. The receptacle connector, such as a socket or a hole connector, is configured to accept such an insertable connector therein. The insertable connector, such as a plug or a pin, is configured to be insertable into such a receptable connector.

If the component 20, which is one of a pair of an insertable connector and a receptacle connector, is mounted to deviate from the designed mount location of the mount portion 11, this deviation of the component 20, which is one of the pair of an insertable connector and a receptacle connector, would require adjustment of the location of the other thereof for alignment of the one of the pair of an insertable connector and a receptacle connector with the other thereof.

In contrast, the above configuration of the mount board 10 eliminates, even if the component 20, which is one of the pair of an insertable connector and a receptacle connector, is mounted to deviate from the designed mount location of the mount portion 11, the necessity to adjust the location of the other thereof.

The mount board 10 according to the exemplary embodiment is configured such that the attachment face 41 of each of the attachment members 40 is formed to have an inclination that is in conformity with the inclination of the component 20 with respect to the designed mount location of the mount portion 11. The present disclosure is not limited to the above configuration.

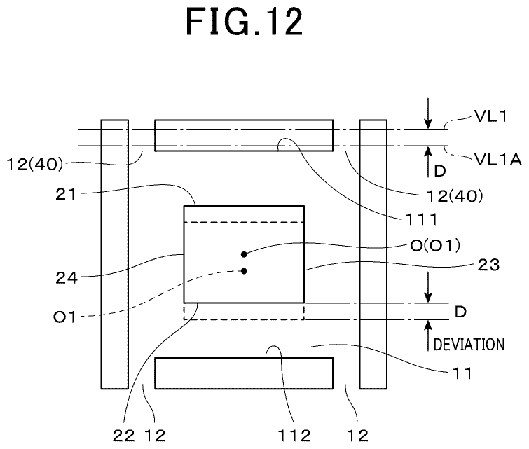

Specifically, let us assume that the component 20 of the upper-center mount board 10A2 is mounted on the mount portion 11 to deviate from the designed mount location by a deviation D in the extending direction of the second side faces 23 and 24 from the designed mount location on the mount portion 11 (see FIG. 12).

In this case, the deviation information calculation process in step S5 uses the image processing apparatus 60 to calculate, for the upper-center mount board 10A2, the deviation information representing a lower deviation of the actual mount location of the component 20 of the upper-center mount board 10A2 from the designed mount location of the component 20 thereof by the deviation D.

Then, the deviation correction cutting process in step S6 cuts each attachment member 12 (40) extending outwardly from the long side 111 of the mount portion 11 of the upper-center mount board 10A2 along a virtual cutting plane VL1A that is shifted to pass through a corrected cutting point that is shifted by the deviation D from the predetermined normal cutting point through which the normal virtual cutting line VL1 passes. Additionally, the deviation correction cutting process cuts each remaining joint 12 extending outwardly from the long side 112 of the mount portion 11 of the upper-center mount board 10A2 along the normal virtual cutting plane VL2 that passes through the predetermined normal cutting point of the corresponding joint 12 in its length direction and is parallel to the long side 112 of the corresponding mount board 10.

One or more components in the exemplary embodiment are not necessarily essential components except for (i) one or more components that are described as one or more essential components or (ii) one or more components that are essential in principle.

Specific values disclosed in the exemplary embodiment, each of which represents the number of components, a physical quantity, and/or a range of a physical parameter, are not limited thereto except that (i) the specific values are obviously essential or (ii) the specific values are essential in principle.

The specific structural or functional relationship between components described in each of the exemplary embodiments is not limited thereto except for cases in which (1) the specific structural or functional relationship is described to be essential or (2) the specific structural or functional relationship is required in principle.

The present disclosure includes the following first to fifth technological concepts.

The first technological concept is a mount board (10) to be attached to a housing (30) as an attachment target. The mount board includes a component (20) and a mount portion (11) on which the component is mounted while deviating from a designed mount location of the mount portion. The mount board includes at least one attachment member (40) joined to the mount portion. The at least one attachment member is configured to be attached to the housing. The at least one attachment member has a configuration defined to be in conformity with information about the deviation of the component from the designed mount location of the mount portion.

In the second technological concept, which depends from the first technological concept, the housing has at least an inner peripheral face to which the mount board is attached. The at least one attachment member of the mount board has an attachment face (41) to be attached to the inner peripheral face of the housing. The component (20) is mounted to be inclined with respect to the designed mount location of the mount portion or linearly deviate from the designed mount location. The attachment face of the at least one attachment member is formed to have an inclination that is in conformity with an inclination of the component with respect to the designed mount location of the mount portion or the at least one attachment member is formed to have a specific configuration that is in conformity with a linear deviation of the component with respect to the designed mount location of the mount portion.

The third technological concept is an assembly board (1). The assembly board includes a plurality of mount boards, each of the mount boards is the mount board according to the first technological concept, and a frame arranged to surround the mount boards and combine the mount boards with each other as an assembly. Each of the mount boards includes at least one joint (12) joined to the mount portion. The at least one joint of each of the mount boards is configured to be cuttable for separation of the corresponding one of the mount boards from the assembly board. The at least one joint serves as the at least one attachment member.

In the fourth technological concept, which depends from the first technological concept, the component is an image sensor.

The fifth technological concept is a method of manufacturing a plurality of mount boards (10) to be attached to a housing. The method 5 includes
(I) Preparing an assembly board that includes the plurality of mount boards, each of which comprising a mount portion (11) and at least one joint (12) joined to the mount portion, and a frame (3) arranged to surround the mount boards and combine the mount boards with each other as an assembly, the at least one joint of each mount board being configured to join the frame and the mount portion of the corresponding mount board
(II) Mounting a component on the mount portion of each of the mount boards in accordance with a designed mount location of the mount portion
(III) Detecting an actual mount location of the component on the mount portion of each of the mount boards
(IV) Determining whether the detected actual mount location of the component on the mount portion of each of the mount boards deviates from the designed mount location of the mount portion of the corresponding one of the mount boards
(V) Calculating, in response to determination that the detected actual mount location of the component on the mount portion of at least one mount board in the mount boards deviates from the designed mount location of the mount portion of the corresponding at least one mount board, information about the deviation of the component of the mount portion of the at least one mount board from the designed mount location of the mount portion thereof
(VI) Cutting the at least one joint of each of the mount boards to accordingly separate each of the mount boards from the assembly board.

The cutting step includes cutting, in response to determination that the detected actual mount location of the component on the mount portion of the at least one mount board deviates from the designed mount location of the mount portion of the corresponding at least one mount board, the at least one joint of the at least one mount board in accordance with the calculated information about the deviation of the component of the mount portion of the at least one mount board from the designed mount location of the mount portion thereof. The at least one joint of each of the mount boards after the cutting step serves as at least one attachment member to be attached to the housing. The at least one attachment member of the at least one mount board has a configuration defined to be in conformity with the calculated information about the deviation of the component from the designed mount location of the mount portion of the at least one mount board.

In the sixth technological concept, which depends from the fifth technological concept, the housing has at least an inner peripheral face to which the mount board is attached. The at least one attachment member of the mount board has an attachment face to be attached to the inner peripheral face of the housing. The determination step determines whether the detected actual mount location of the component on the mount portion of each of the mount boards deviates from the designed mount location of the mount portion of the corresponding one of the mount boards, so that the component is mounted to be inclined with respect to the designed mount location of the mount portion or linearly deviate from the designed mount location. The cutting step causes (i) the attachment face of the at least one attachment member to be formed to have an inclination that is in conformity with an inclination of the component with respect to the designed mount location of the mount portion or (ii) the at least one attachment member to have a specific configuration that is defined to be in conformity with a linear deviation of the component with respect to the designed mount location of the mount portion.

1. A mount board to be attached to a housing as an attachment target, the mount board comprising:
a component;
a mount portion on which the component is mounted while deviating from a designed mount location of the mount portion; and
at least one attachment member joined to the mount portion, the at least one attachment member being configured to be attached to the housing,
the at least one attachment member comprising a configuration defined to be in conformity with information about the deviation of the component from the designed mount location of the mount portion.

2. The mount board according to claim 1, wherein:
the housing has at least an inner peripheral face to which the mount board is attached;
the at least one attachment member of the mount board has an attachment face to be attached to the inner peripheral face of the housing;
the component is mounted to be inclined with respect to the designed mount location of the mount portion or linearly deviate from the designed mount location; and
the attachment face of the at least one attachment member is formed to have an inclination that is in conformity with an inclination of the component with respect to the designed mount location of the mount portion or the at least one attachment member is formed to have a specific configuration that is in conformity with a linear deviation of the component with respect to the designed mount location of the mount portion.

3. An assembly board comprising:
a plurality of mount boards, each of the mount boards being the mount board according to claim 1; and
a frame arranged to surround the mount boards and combine the mount boards with each other as an assembly,
each of the mount boards including at least one joint joined to the mount portion, the at least one joint of each of the mount boards being configured to be cuttable for separation of the corresponding one of the mount boards from the assembly board,
the at least one joint serving as the at least one attachment member.

4. The mount board according to claim 1, wherein:
the component is an image sensor.

5. A method of manufacturing a plurality of mount boards to be attached to a housing, the method comprising:
preparing an assembly board that comprises:
the plurality of mount boards, each of which comprises a mount portion and at least one joint joined to the mount portion; and
a frame arranged to surround the mount boards and combine the mount boards with each other as an assembly, the at least one joint of each mount board being configured to join the frame and the mount portion of the corresponding mount board;
mounting a component on the mount portion of each of the mount boards in accordance with a designed mount location of the mount portion;
detecting an actual mount location of the component on the mount portion of each of the mount boards;
determining whether the detected actual mount location of the component on the mount portion of each of the mount boards deviates from the designed mount location of the mount portion of the corresponding one of the mount boards;
calculating, in response to determination that the detected actual mount location of the component on the mount portion of at least one mount board in the mount boards deviates from the designed mount location of the mount portion of the corresponding at least one mount board, information about the deviation of the component of the mount portion of the at least one mount board from the designed mount location of the mount portion thereof; and
cutting the at least one joint of each of the mount boards to accordingly separate each of the mount boards from the assembly board,
the cutting step comprising:
cutting, in response to determination that the detected actual mount location of the component on the mount portion of the at least one mount board deviates from the designed mount location of the mount portion of the corresponding at least one mount board, the at least one joint of the at least one mount board in accordance with the calculated information about the deviation of the component of the mount portion of the at least one mount board from the designed mount location of the mount portion thereof,
the at least one joint of each of the mount boards after the cutting step serving as at least one attachment member to be attached to the housing,
the at least one attachment member of the at least one mount board comprising a configuration defined to be in conformity with the calculated information about the deviation of the component from the designed mount location of the mount portion of the at least one mount board.

6. The method according to claim 5, wherein:
the housing has at least an inner peripheral face to which the mount board is attached;
the at least one attachment member of the mount board has an attachment face to be attached to the inner peripheral face of the housing;
the determination step determines whether the detected actual mount location of the component on the mount portion of each of the mount boards deviates from the designed mount location of the mount portion of the corresponding one of the mount boards, so that the component is mounted to be inclined with respect to the designed mount location of the mount portion or linearly deviate from the designed mount location; and
the cutting step causes (i) the attachment face of the at least one attachment member to be formed to have an inclination that is in conformity with an inclination of the component with respect to the designed mount location of the mount portion or (ii) the at least one attachment member to have a specific configuration that is defined to be in conformity with a linear deviation of the component with respect to the designed mount location of the mount portion.
